(19) United States
(12) Patent Application Publication
(10) Pub. No.: US 2023/0143258 A1
(43) Pub. Date: May 11, 2023

(54) SOLID-STATE IMAGE SENSOR

(71) Applicant: TOPPAN Inc., Taito-ku (JP)

(72) Inventor: Wataru NOZAKI, Taito-ku (JP)

(73) Assignee: TOPPAN Inc., Taito-ku (JP)

(21) Appl. No.: 18/090,841

(22) Filed: Dec. 29, 2022

Related U.S. Application Data
(63) Continuation of application No. PCT/JP2021/024365, filed on Jun. 28, 2021.

(30) Foreign Application Priority Data
Jun. 30, 2020 (JP) 2020-112690
Aug. 7, 2020 (JP) 2020-134980
Aug. 7, 2020 (JP) 2020-134981

(51) Int. Cl. H01L 27/146

(52) U.S. Cl. CPC H01L 27/14627; H01L 27/14621

(57) ABSTRACT

A solid-state image sensor including a wafer substrate including photoelectric conversion elements, a filter module formed over the wafer substrate and including different color filters each aligned with a different one of the photoelectric conversion elements, each of the color filters being formed in a different one of color filter regions, and a microlens module including microlenses each aligned with a different one of the color filters. The microlens module includes main lenses each formed within a corresponding one of the color filter regions in a plan view, and auxiliary lenses formed in different corner portions of the color filter regions, and having a lens parameter different from a lens parameter of the main lenses.

### CROSS-REFERENCE TO RELATED APPLICATIONS

The present application is a continuation of International Application No. PCT/JP2021/024365, filed Jun. 28, 2021, which is based upon and claims the benefits of priority to Japanese Application No. 2020-112690, filed Jun. 30, 2020, Japanese Application No. 2020-134980, filed Aug. 7, 2020, and Japanese Application No. 2020-134981, filed Aug. 7, 2020. The entire contents of all of the above applications are incorporated herein by reference.

### BACKGROUND OF THE INVENTION

### Field of the Invention

The present invention relates to solid-state image sensors, and more specifically, to a solid-state image sensor of an on-chip type that has a color filter and a microlens array mounted thereon.

### Discussion of the Background

Single-chip solid-state image sensors are in widespread use in which color information on an object can be obtained by providing, in the path of light incident on photoelectric conversion elements, a color filter in which different colored transparent patterns are arranged in a plane that selectively transmit light of specific wavelengths.

As color solid-state image sensors are becoming increasingly thinner, more lightweight, and higher resolution, on-chip type solid-state image sensors are being increasingly used that have a color filter directly formed on the substrate where photoelectric conversion elements are arranged.

In on-chip type solid-state image sensors, microlenses may be provided to efficiently guide light to photoelectric conversion elements (see, for example, JP 2013-008777 A).

### SUMMARY OF THE INVENTION

According to an aspect of the present invention, a solid-state image sensor includes a wafer substrate including photoelectric conversion elements, a filter module formed over the wafer substrate and including different color filters each aligned with a different one of the photoelectric conversion elements, each of the color filters being formed in a different one of color filter regions, and a microlens module including microlenses each aligned with a different one of the color filters. The microlens module include main lenses each formed within a corresponding one of the color filter regions in a plan view, and auxiliary lenses formed in different corner portions of the color filter regions, and having a lens parameter different from a lens parameter of the main lenses.

According to another aspect of the present invention, a solid-state image sensor includes a wafer substrate including photoelectric conversion elements, a filter module formed over the wafer substrate and including different color filters each aligned with a different one of the photoelectric conversion elements, each of the color filters being formed in a different one of color filter regions, and a microlens module including microlenses each aligned with a different one of the color filters. In the microlenses, each two microlenses adjacent to each other in respective diagonal directions of the color filter regions have a diagonal gap defined as a minimum distance therebetween, and the diagonal gap is 15%-25% of a longest side of a shape of each color filter region in a plan view.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic cross-sectional view illustrating a solid-state image sensor according to a first embodiment of the present invention.

FIG. 2 is an image of a conventional microlens module in plan view.

FIG. 3 is a diagram illustrating a gap region.

FIG. 4 is a partial plan view illustrating a microlens module according to the first embodiment.

FIG. 5 is an electron microscope image obtained during production of the microlens module according to the first embodiment.

FIG. 6 is an electron microscope image of an example microlens module produced according to the first embodiment.

FIG. 7 is a partial enlarged view schematically illustrating a microlens module according to a modification of the first embodiment.

FIG. 8 is a graph illustrating the result of a simulation of the relationship between the diagonal gap in a microlens module of a solid-state image sensor according to a second embodiment, and light reflected by an optical surface of a microlens in a direction other than a normal direction.

FIG. 9 is a graph illustrating the result of a simulation of the relationship between the thickness of microlenses in the solid-state image sensor according to the second embodiment, and light reflected by an optical surface of a microlens in a direction other than a normal direction.

FIG. 10 is a graph illustrating the result of a simulation of the relationship between the occupancy ratio of a microlens in a color filter region of a solid-state image sensor according to a third embodiment, and light reflected by an optical surface of a microlens in a direction other than a normal direction.

FIG. 11 is a plan view image of microlenses according to an Example.

FIG. 12 is an image of petal flare occurring in a solid-state image sensor according to a Comparative Example.

FIG. 13 is an image of petal flare occurring in a solid-state image sensor according to the Example.

### DESCRIPTION OF THE EMBODIMENTS

The embodiments will now be described with reference to the accompanying drawings, wherein like reference numerals designate corresponding or identical elements throughout the various drawings.

With reference to the drawings, embodiments of the present invention will be described.

In the drawings to be referred to in the following description, the scale of individual components is appropriately changed to make each component recognizable. The dimensions and proportions of the respective components are modified from actual ones as appropriate.

### First Embodiment

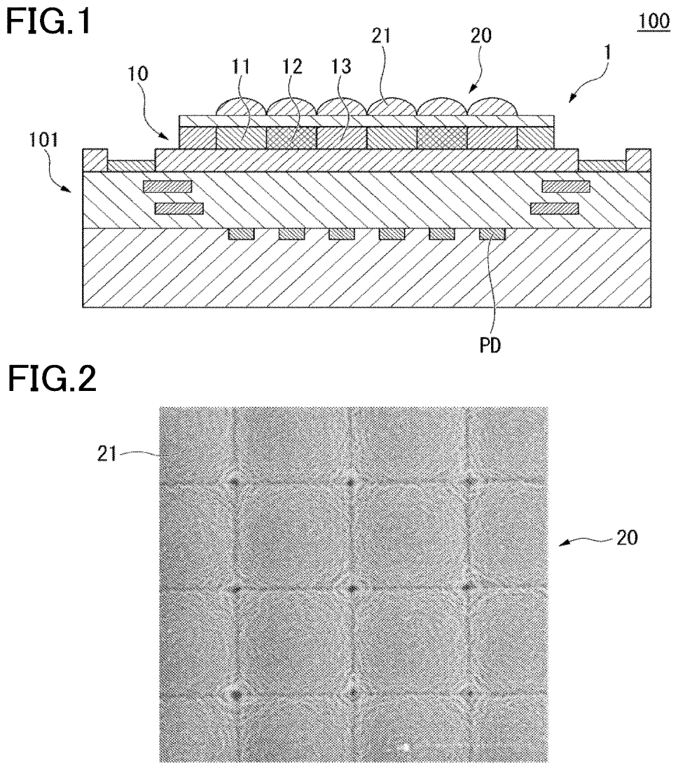

With reference to FIGS. 1 to 4, a solid-state image sensor according to a first embodiment will be described.

FIG. 1 is a schematic cross-sectional view illustrating the solid-state image sensor according to the first embodiment. A solid-state image sensor 100 includes a wafer substrate 101 including a plurality of photoelectric conversion elements PD, and an on-chip color filter 1 disposed on the wafer substrate 101.

The on-chip color filter 1 includes a filter module 10 containing different color filters, and a microlens module 20 disposed on the filter module 10.

The filter module 10 includes three types of color filters, namely color filters 11, 12 and 13. The type, number, and distribution of colors in the filter module 10 can be appropriately determined, and the type, number, and distribution of colors known in the art can be adopted for the filter module 10. For example, a Bayer pattern using three colors of red, green, and blue may be used. As viewed perpendicular to the solid-state image sensor 100, each color filter overlaps a different one of the photoelectric conversion elements PD.

The microlens module 20 includes a plurality of microlenses. The microlenses include main lenses 21 (microlenses) that guide light to the respective photoelectric conversion elements PD, and auxiliary lenses disposed around the main lenses 21. The auxiliary lenses are not illustrated in FIG. 1 because they are not present in cross section shown in FIG. 1, and will be described later in detail.

The main lenses 21 are arranged in approximately the same manner as the color filters of the filter module 10, and as viewed perpendicular to the solid-state image sensor 100, the color filters each overlap a different one of the main lenses 21. That is, as viewed perpendicular to the on-chip color filter 1, each of the main lenses 21 is located within a corresponding one of color filter regions respectively having a color filter disposed therein.

In the solid-state image sensor 100, light incident on the main lens 21 is guided to the photoelectric conversion element PD through the corresponding color filter, and thus the solid-state image sensor 100 performs an imaging function.

For improved sensitivity of a solid-state image sensor, it is necessary to guide as much light as possible to photoelectric conversion elements using microlenses. For this reason, it is well-known to form microlenses of a microlens module using a known technique such as thermal reflow and etchback such that optical surfaces of the microlenses are located within different color filter regions with substantially no gap as illustrated in FIG. 2.

Unfortunately, for solid-state image sensors having such a high resolution that in plan view the diameter of microlenses or the length of each side of color filters arranged above the respective microlenses is 1.2 μm or less, a phenomenon occasionally occurs where insufficient color purity is obtained.

The inventor studied this phenomenon and found that petal flare due to microlenses is a main cause thereof.

Petal flare is a type of flare that occurs in the form of spaced petals located around the optical axis of a microlens. It is considered that petal flare occurs due to interference of light reflected by an optical surface of a microlens in a direction other than a normal direction. It is considered that although petal flare itself occurs in conventional microlens arrays in theory, the occurrence of petal flare has not conventionally surfaced as a problem because, for example, the amount of light received by a photoelectric conversion element is large, or the distance (pitch) between adjacent color filter regions is large.

The inventor studied various methods of reducing petal flare. Consequently, it was found that providing a microlens module with auxiliary lenses in addition to main lenses is effective.

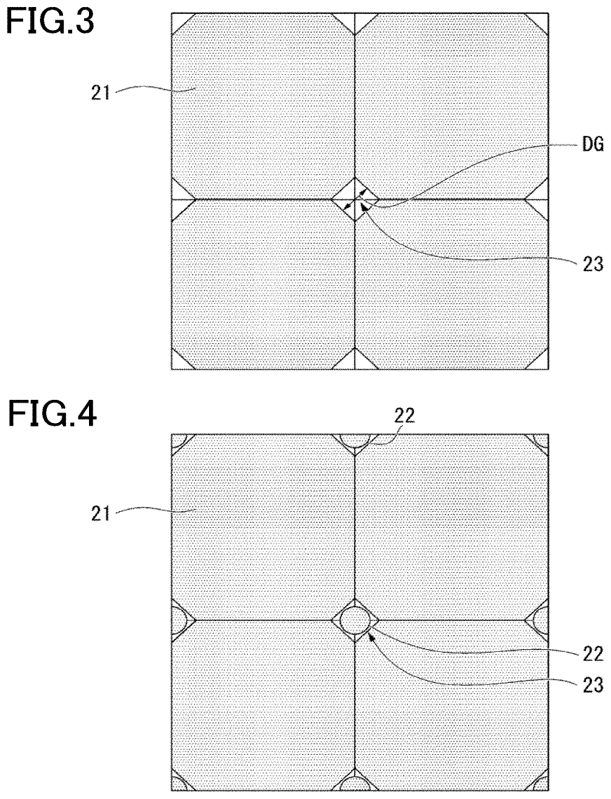

In the case where the shape of individual color filter regions, each having a color filter disposed therein, is a square in plan view, setting the diameter of microlenses to approximately the same length as diagonal lines of the square allows the microlenses to be located within the respective color filter regions with no gap as illustrated in FIG. 2. Reducing the diameter of the microlenses arranged in this state results in formation of gap regions 23 each located at corners of the color filter regions and having no microlens formed therein as illustrated in FIG. 3. Each gap region is configured to include corner portions of adjacent color filter regions.

In the first embodiment, auxiliary lenses 22 smaller in diameter than the main lenses are provided in the respective gap regions 23 as illustrated in FIG. 4, thus successfully reducing petal flare.

Although the mechanism by which the provision of the auxiliary lenses 22 reduces petal flare has not been completely confirmed, the following effects seem to be the main factors.

Part of light incident on the microlens module 20 enters the auxiliary lenses 22. Consequently, this part of the light is reflected by each optical surface of the auxiliary lenses 22 as reflected light in a direction other than a normal direction as with the main lenses 21. However, this reflected light differs in phase from light reflected by the main lenses because the main lenses and auxiliary lenses have different dimensions.

For this reason, when reflected light from main lenses and reflected light from auxiliary lenses interfere with each other, they act to cancel out petal flare, and thus petal flare is considered to be reduced.

In view of the above mechanism, the effect of reducing petal flare can be expected when at least one of the lens parameters for the auxiliary lenses 22 is different from that for the main lenses 21. In other words, the effect of reducing petal flare can be obtained when the main lenses 21 and the auxiliary lenses 22 differ from each other in dimension, shape, or the like. Since the auxiliary lenses 22 are formed in the respective gap regions 23 where the main lenses 21 are not located, an exceedingly large diameter of the auxiliary lenses 22 means that the main lenses each have a small diameter, which disadvantageously reduces the amount of light that can be guided to the corresponding photoelectric conversion element PD. From this viewpoint, the diameter of the auxiliary lenses 22 is preferably less than the diameter of the main lenses 21, and is more preferably about 1% or more and 30% or less thereof.

In the auxiliary lenses 22, a lens parameter different from that for the main lenses is not limited to the diameter. In the auxiliary lenses 22, a parameter other than a diameter, such as those mentioned below as examples, may be set singly or in appropriate combination with the diameter, which enables efficient reduction of petal flare in the solid-state image sensor 100 produced.
Height
Area ratio of auxiliary lens in gap region
Shape in plan view (elliptical shape, oval shape, or the like)

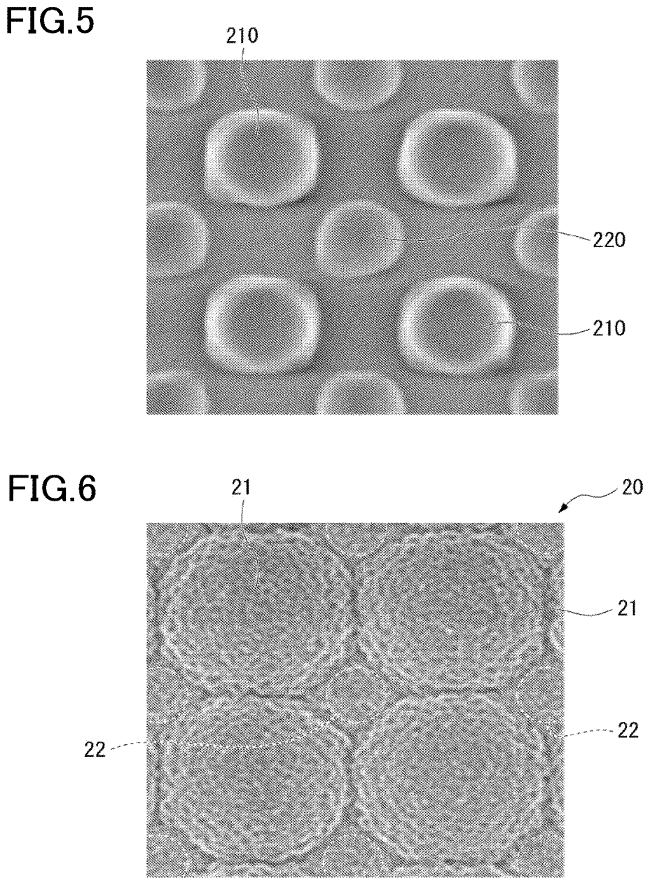

The auxiliary lenses 22 are formed using the same method as for the main lenses 21, and thus the auxiliary lenses can be formed together with the main lenses by a process during formation of the main lenses. More specifically, by appropriately setting a mask design and performing a photolithography process, second precursors 220 which will become auxiliary lenses are formed between first precursors 210 which will become main lenses as illustrated in FIG. 5. Subsequently, the first precursors 210 and second precursors 220 are subjected to etchback, and thus, as illustrated in FIG. 6, the microlens module 20 according to the first embodiment is formed such that the auxiliary lenses 22 are disposed around the main lenses 21.

The first embodiment of the present invention has been described, but specific configurations of the present invention are not limited to the first embodiment described above.

### Modification of First Embodiment

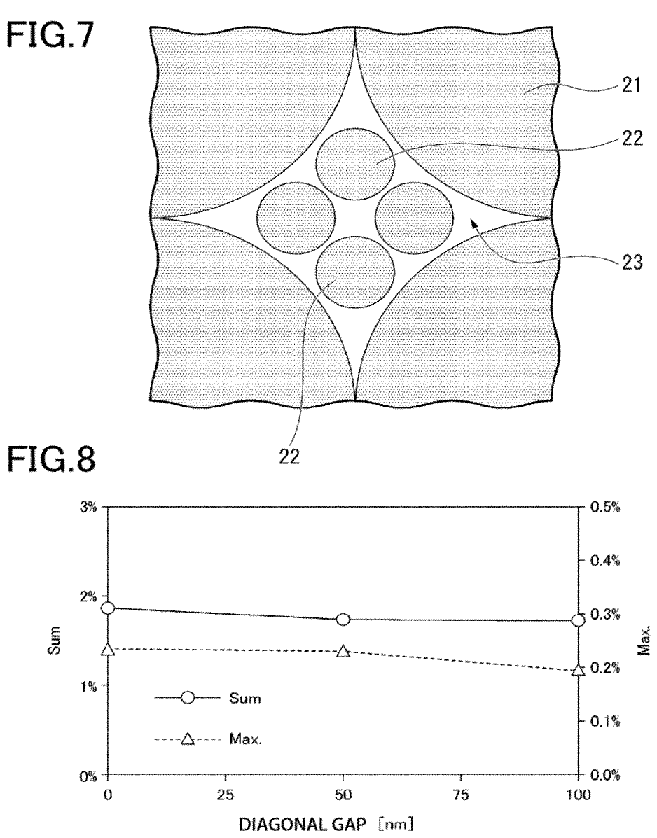

For example, as with the modification illustrated in FIG. 7, a plurality of auxiliary lenses 22 may be disposed in each gap region 23. In this case, the shapes of the plurality of auxiliary lenses 22 may be the same as or different from each other. The number and arrangement of the auxiliary lenses 22 are also not particularly limited and may be appropriately set.

Further, the auxiliary lenses 22 may not extend over adjacent color filters. In other words, each gap region 23 may be formed above a different one of the color filters, and one main lens 21 and one or more auxiliary lenses 22 may be formed above the respective color filters. That is, one main lens 21 and one or more auxiliary lenses 22 may be formed above a single color filter.

### Second Embodiment

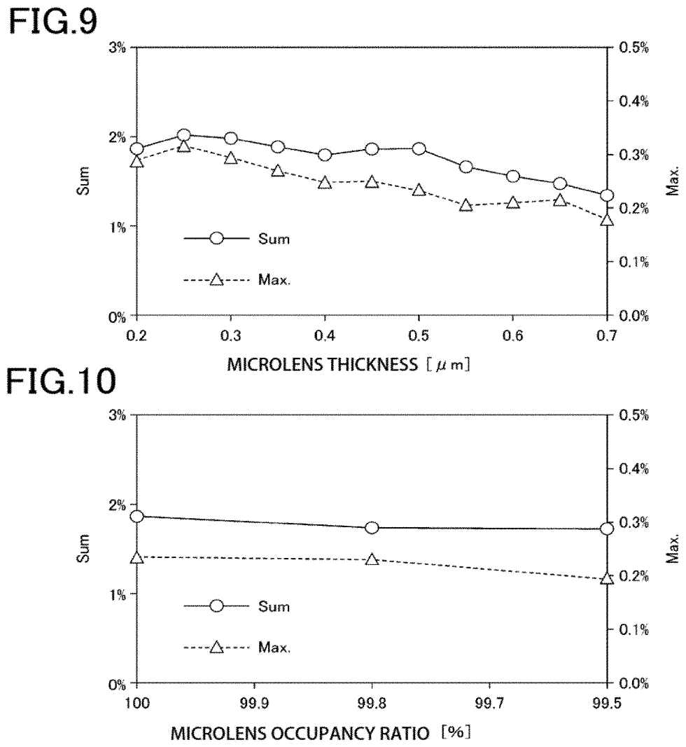

With reference to FIGS. 8 and 9, a solid-state image sensor according to a second embodiment will be described.

The solid-state image sensor according to the second embodiment differs from the first embodiment in that auxiliary lenses are not used. In the second embodiment, the same components as those of the first embodiment will be referred to by the same reference signs and the description thereof will be omitted or simplified.

The inventor studied various methods of reducing petal flare. Consequently, it was found that providing a certain amount of a gap region with no microlens as viewed perpendicular to the microlens module is effective.

In the case of individual color filters having a square shape in plan view, setting the diameter of microlenses to approximately the same length as diagonal lines of the square shape allows arrangement of the microlenses with no gap as illustrated in FIG. 2. Reducing the diameter of the microlenses arranged in this state results in formation of gap regions each located at corners of the square shape and having no microlens formed therein as illustrated in FIG. 3.

FIG. 8 shows the result of a simulation of the relationship between the diagonal gap in a gap region, and the amount of light reflected in a direction other than a normal direction. The shape of a color filter region was set to a square with a side of 1.1 μm.

The term “diagonal gap” refers to a minimum distance between a first microlens disposed above any color filter region as a first color filter region and a second microlens disposed above any one of color filter regions that are located around the first color filter region as second color filter regions and touch the first color filter region only at their respective corners, where the minimum distance is determined along each line passing through the corners at which the first color filter region and the respective second color filter regions touch each other. That is, the diagonal gap is a minimum distance between any microlens and another microlens adjacent to that microlens in a diagonal direction in plan view. Note that, in the case of the color filters being separated by a dividing wall and thus disposed such that corners of each two color filters aligned in a diagonal direction do not touch each other, the diagonal gap is a distance including the dividing wall.

As can be seen from FIG. 8, as the diagonal gap increases, light reflected in a direction other than a normal direction decreases. Although an exceedingly small microlens relative to a color filter region guides less light to a photoelectric conversion element, resulting in lower sensitivity, a study conducted by the inventor revealed that when a diagonal gap is 15% or more and 25% or less of the length of a side of color filter regions each corresponding to the diagonal gap, light reflected in a direction other than a normal direction can be reduced with almost no influence on performance such as sensitivity.

Further, a study conducted by the inventor revealed that the thickness of microlenses has an influence on petal flare. That is, by designing the diagonal gap to be within a predetermined range and then adjusting the thickness of microlenses as below, petal flare can be further reduced.

FIG. 9 shows the result of a simulation of the relationship between the thickness of microlenses and the amount of light reflected in a direction other than a normal direction. Various conditions such as dimensions of a color filter region were the same as those in the simulation according to FIG. 8.

As can be seen from FIG. 9, as the thickness of microlenses increases, light reflected in a direction other than a normal direction decreases. A study conducted by the inventor revealed that when the thickness of each microlens is 50% or more and 65% or less of the length of a side of the corresponding color filter region, light reflected in a direction other than a normal direction can be reduced with almost no influence on performance such as sensitivity. Further, each microlens more preferably has a thickness of 50% or more and 54% or less of the length of a side of the corresponding color filter region because this range of thicknesses can achieve, at high levels, improvement in light collection efficiency and reduction in light reflected in a direction other than a normal direction.

In FIGS. 8 and 9, “Sum” refers to the sum of all diffracted light, and “Max” refers to the most strongly diffracted light of all diffraction orders. These both have an influence on petal flare, but reducing the value of Max is more effective in reducing petal flare.

### Third Embodiment

With reference to FIG. 10, a solid-state image sensor according to a third embodiment will be described.

The solid-state image sensor according to the third embodiment differs from the first embodiment in that auxiliary lenses are not used. In the third embodiment, the same components as those of the first embodiment will be referred to by the same reference signs and the description thereof will be omitted or simplified.

The inventor studied various methods of reducing petal flare. Consequently, it was found that reducing the region where microlenses are disposed as viewed perpendicular to the microlens module is effective.

In the case of individual color filters having a square shape in plan view, setting the diameter of microlenses to approximately the same length as diagonal lines of the square shape allows arrangement of the microlenses with no gap as illustrated in FIG. 2. Reducing the diameter of the microlenses arranged in this state results in formation of gap regions 23 (non-occupied regions) each located at corners of the color filter regions and having no main lenses 21 (microlenses) formed therein as illustrated in FIG. 3.

FIG. 10 shows the result of a simulation of the relationship between an occupancy ratio defined as the ratio of an area of a microlens covering the corresponding color filter region, and the amount of light reflected in a direction other than a normal direction. The shape of a color filter region was set to a square with a side of 1.1 μm.

The occupancy ratio may be determined, for example, by the following expression (1) or (2), but is not limited to this. The occupancy ratio may be determined, for example, by subjecting a plan view image of a color filter region to image processing (e.g., counting pixels).

area of microlens in plan view/area of color filter region in plan view×100(%) (1)

(area of color filter region in plan view−area of non-occupied region in plan view)/area of color filter region in plan view×100(%) (2)

As can be seen from FIG. 10, as the occupancy ratio decreases, light reflected in a direction other than a normal direction decreases. Although an exceedingly small occupancy ratio relative to a color filter region reduces the amount of light guided to a photoelectric conversion element, resulting in lower sensitivity, a study conducted by the inventor revealed that when the occupancy ratio is 90% or more and 95% or less, light reflected in a direction other than a normal direction can be reduced with almost no influence on performance such as sensitivity.

Further, a study conducted by the inventor revealed that the thickness of microlenses has an influence on petal flare. That is, by designing the occupancy ratio to be within a predetermined range and then adjusting the microlens thickness as below, petal flare can be further reduced.

FIG. 9 is a diagram described in the above second embodiment, showing the result of a simulation of the relationship between the microlens thickness and the amount of light reflected in a direction other than a normal direction. Various conditions such as dimensions of a color filter region were the same as those in the simulation according to FIG. 10.

As can be seen from FIG. 9, as the thickness of microlenses increases, light reflected in a direction other than a normal direction decreases. A study conducted by the inventor revealed that when the thickness of each microlens is 65% or less of the length of a side of the corresponding color filter region, light reflected in a direction other than a normal direction can be reduced with almost no influence on performance such as sensitivity.

In FIGS. 9 and 10, “Sum” refers to the sum of all diffracted light, and “Max” refers to the most strongly diffracted light of all diffraction orders. These both have an influence on petal flare, but reducing the value of Max is more effective in reducing petal flare.

The solid-state image sensors according to the first embodiment, the modification of the first embodiment, the second embodiment, and the third embodiment have been described. The solid-state image sensor of the present invention encompasses modifications, combinations, and the like in the configurations, in the range not departing from the spirit of the present invention.

For example, the shape of each color filter region is not limited to the square shape described above, and may be a rectangular shape or any other polygonal shape. In the case of each color filter region having a shape with sides of different lengths as with a rectangular shape or the like, the thickness, diagonal gap, and the like are set relative to the length of the longest side of the shape.

For example, in the solid-state imaging device of the present invention, color filters may not be disposed in part thereof in plan view.

For example, in the case where the present invention is applied to a solid-state image sensor or the like in which some of the photoelectric conversion elements are used for focus adjustment or the like, a possible configuration may be such that color filters are not disposed in a region of a filter module corresponding to the photoelectric conversion elements used for focus adjustment.

Similarly, the solid-state image sensor according to the present invention may have a gap region where no auxiliary lens is disposed.

To prevent stray light, a dividing wall may be formed between the color filters. The dividing wall may be a light absorbing dividing wall, or light reflective dividing wall.

### EXAMPLES

The solid-state image sensors according to the above-described second and third embodiments will be further described using examples and comparative examples. The technical scope of the present invention is not limited by the description of the examples and comparative examples.

### Example 1

A plurality of photoelectric conversion elements arranged in a two-dimensional matrix and a wafer substrate including metal wirings and the like were prepared. Color filters of three colors, namely G (Green), R (Red) and B (Blue), were formed in a Bayer pattern on this wafer substrate so as to face the respective photoelectric conversion elements, thus providing a filter module above the wafer substrate.

A transparent layer composed of a non-photosensitive resin was formed on the filter module with a coater, a hardmask composed of a photosensitive resin was applied to the transparent resin and subjected to exposure and development, and lens patterns having a circular shape in plan view were formed so as to be located within different color filter regions.

These lens patterns were subjected to a thermal flow process at 160° C. for 300 seconds so as to have a hemispherical shape, and the lens patterns and transparent layer were etched by an etching process.

Thus, the solid-state image sensor according to Example 1 was produced. Dimensions of respective parts in Example 1 were as follows.

Color filter region: A square shape with a side of 1.1 μm

Microlens thickness: 0.58 μm (52.7% of the above side)

Microlens diagonal gap: 0.1 μm (9.09% of the above side)

Microlens occupancy ratio: 99.5%<

### Comparative Example

A solid-state image sensor according to a comparative example, provided with a color filter, was produced by the same process as that for Example 1 except that the etching process was changed to provide a microlens thickness of 0.52 μm (47.3% of the above side).

### Example 2

A solid-state image sensor according to Example 2, provided with a color filter, was produced by the same process as that for Example 1 except that the lens patterns and the etching process were changed to provide a diagonal gap of 0.27 μm (24.5% of the above side), and the microlens occupancy ratio was changed to 94.0%.

The highest intensities of petal flare for respective colors in Example 1 and Comparative Example are shown in Table 1. Table 1 shows relative values, with the highest intensities of Comparative Example being 100.

TABLE 1

| | R | G | B |
|---|---|---|---|
| Example 1 | 53.4 | 76.7 | 78.9 |
| Comparative Example | 100.0 | 100.0 | 100.0 |

As shown in Table 1, in Example 1, the highest intensities of petal flare were reduced by 20% or more in each of the color filters.

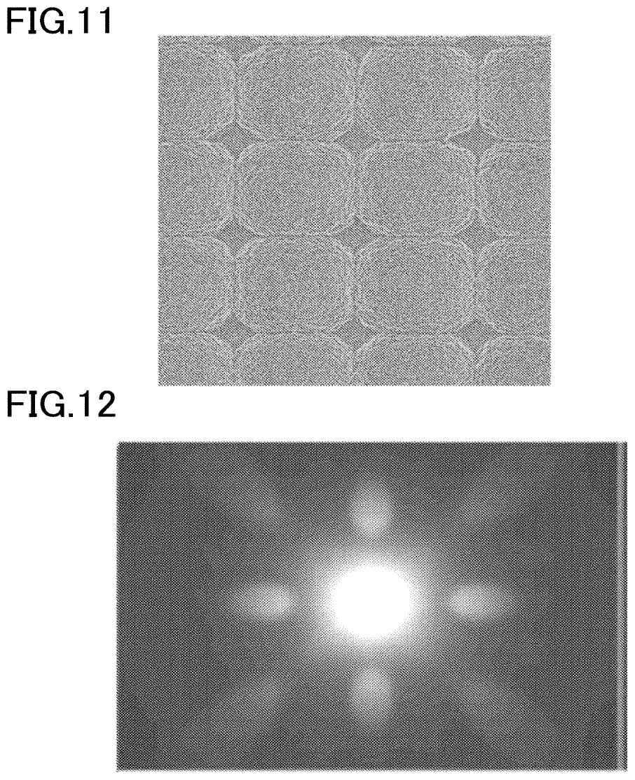

FIG. 11 is a plan view image obtained with a scanning electron microscope (SEM), showing a microlens module according to Example 2. As can be seen from FIG. 11, compared with FIG. 2, relatively large diagonal gaps (non-occupied regions) were provided at corner portions of the color filter regions.

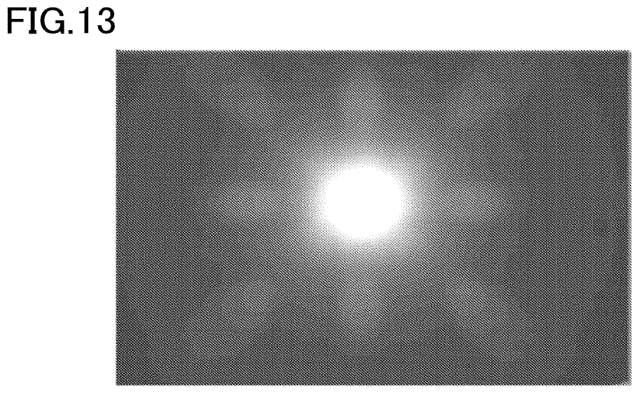

FIG. 12 is an image showing petal flare in Comparative Example, whereas FIG. 13 is an image showing petal flare in Example 2. As can be seen from these figures, the degree of petal flare was lower in Example 2 than in Comparative Example.

The present application addresses the following. As digital/imaging devices are becoming higher in image quality and smaller in size, there is a demand for even higher definition in on-chip type solid-state image sensors.

In the process of studying how to achieve higher resolution in such solid-state image sensors, the inventor recognized a new problem of petal flare, which has not conventionally been perceived as a problem, and has solved this problem.

The present invention has an aspect to provide solid-state image sensors that can achieve higher resolution and reduction of petal flare.

A solid-state image sensor according to an aspect of the present invention includes a wafer substrate including a plurality of photoelectric conversion elements; a filter module disposed over the wafer substrate, the filter module including a plurality of different color filters each arranged to be aligned with a different one of the photoelectric conversion elements, each of the color filters being disposed in a different one of color filter regions; and a microlens module including a plurality of microlenses each arranged to be aligned with a different one of the color filters.

The microlens module includes main lenses each arranged to be located within a corresponding one of the color filter regions in plan view; and auxiliary lenses disposed at different corner portions of the color filter regions, the auxiliary lenses having a lens parameter different from that of the main lenses.

A solid-state image sensor according to an aspect of the present invention includes a wafer substrate including a plurality of photoelectric conversion elements; a filter module disposed over the wafer substrate, the filter module including a plurality of different color filters each arranged to be aligned with a different one of the photoelectric conversion elements, each of the color filters being disposed in a different one of color filter regions; and a microlens module including a plurality of microlenses each arranged to be aligned with a different one of the color filters.

In the microlenses, each two microlenses adjacent to each other in respective diagonal directions of the color filter regions have a diagonal gap defined as a minimum distance therebetween, the diagonal gap being 15% or more and 25% or less of a longest side of a shape of each color filter region in plan view.

A solid-state image sensor according to an aspect of the present invention includes a wafer substrate including a plurality of photoelectric conversion elements; a filter module disposed over the wafer substrate, the filter module including a plurality of different color filters each arranged to be aligned with a different one of the photoelectric conversion elements, each of the color filters being disposed in a different one of color filter regions; and a microlens module including a plurality of microlenses each arranged to be aligned with a different one of the color filters.

As viewed perpendicular to the respective color filter regions, each of the microlenses has an occupancy ratio of 90% or more and 95% or less relative to a corresponding one of the color filter regions.

The present application provides a solid-state image sensor that can achieve higher resolution and reduction of petal flare.

### REFERENCE SIGNS LIST

1 . . . On-chip color filter (color filter)
10 . . . Filter module
11, 12, 13 . . . Color filter
20 . . . Microlens module
21 . . . Main lens (microlens)
22 . . . Auxiliary lens
100 . . . Solid-stage image sensor
101 . . . Wafer substrate
DG . . . Diagonal gap
PD . . . Photoelectric conversion element

Obviously, numerous modifications and variations of the present invention are possible in light of the above teachings. It is therefore to be understood that within the scope of the appended claims, the invention may be practiced otherwise than as specifically described herein.

What is claimed is:

1. A solid-state image sensor, comprising:
a wafer substrate including a plurality of photoelectric conversion elements;
a filter module formed over the wafer substrate and including a plurality of different color filters each aligned with a different one of the photoelectric conversion elements, each of the color filters being formed in a different one of color filter regions; and
a microlens module including a plurality of microlenses each aligned with a different one of the color filters, the microlens module including
a plurality of main lenses each formed within a corresponding one of the color filter regions in a plan view, and
a plurality of auxiliary lenses formed in different corner portions of the color filter regions, and having a lens parameter different from a lens parameter of the main lenses.

2. The solid-state image sensor according to claim 1, wherein the auxiliary lenses extend over corner portions of adjacent ones of the color filter regions.

3. The solid-state image sensor according to claim 1, wherein the auxiliary lenses have a diameter in a plan view smaller than a diameter of the main lenses.

4. The solid-state image sensor according to claim 3, wherein the diameter of the auxiliary lenses is 1%-30% of the diameter of the main lenses.

5. A solid-state image sensor, comprising:
a wafer substrate including a plurality of photoelectric conversion elements;
a filter module formed over the wafer substrate and including a plurality of different color filters each aligned with a different one of the photoelectric conversion elements, each of the color filters being formed in a different one of color filter regions; and
a microlens module including a plurality of microlenses each aligned with a different one of the color filters,
wherein in the microlenses, each two microlenses adjacent to each other in respective diagonal directions of the color filter regions have a diagonal gap defined as a minimum distance therebetween, and the diagonal gap is 15%-25% of a longest side of a shape of each color filter region in a plan view.

6. The solid-state image sensor according to claim 5, wherein each of the microlenses has a thickness of 50%-65% of the longest side of a corresponding one of the color filter regions.

7. The solid-state image sensor according to claim 1, wherein as viewed perpendicular to the respective color filter regions, each of the microlenses has an occupancy ratio of 90%-95% relative to a corresponding one of the color filter regions.

8. The solid-state image sensor according to claim 7, wherein each of the microlenses has a thickness of 50%-65% of a longest side of a shape of a corresponding one of the color filter regions in a plan view.
